(19) United States
(12) Patent Application Publication
(10) Pub. No.: US 2009/0186475 A1
(43) Pub. Date: Jul. 23, 2009

(54) Method of manufacturing a MOS transistor

(76) Inventors: Shyh-Fann Ting, Tai-Nan City (TW); Cheng-Tung Huang, Kao-Hsiung City (TW); Shih-Chieh Hsu, Taipei County (TW); Chih-Chiang Wu, Taichung County (TW); Meng-Yi Wu, Kaohsiung County (TW); Li-Shian Jeng, Tai-Tung Hsien (TW); Chung-Min Shih, Tai-Nan City (TW); Kun-Hsien Lee, Tai-Nan City (TW); Wen-Han Hung, Kao-Hsiung City (TW); Yao-Chin Cheng, Hsinchu City (TW); Chi-Sheng Tseng, Kaohsiung County (TW); Yu-Ming Lin, Tainan County (TW); Shih-Jung Tu, Tainan City (TW); Tzyy-Ming Cheng, Hsin-Chu City (TW)

Correspondence Address: NORTH AMERICA INTELLECTUAL PROPERTY CORPORATION, P.O. BOX 506, MERRIFIELD, VA, 22116, US

(21) Appl. No.: 12/017,065

(22) Filed: Jan. 21, 2008

(51) Int. Cl. H01L 21/3205

(52) U.S. Cl. 438/595; 257/E21.294

(57) ABSTRACT

A method of manufacturing a MOS transistor, in which, a tri-layer photo resist layer is used to form a patterned hard mask layer having a sound shape and a small size, and the patterned hard mask layer is used to form a gate. Thereafter, by forming and defining a cap layer, a recess is formed through etching in the substrate. The patterned hard mask is removed after epitaxial layers are formed in the recesses. Accordingly, a conventional poly bump issue and an STI oxide loss issue leading to contact bridge can be avoided.

### BACKGROUND OF THE INVENTION

1. Field of the Invention

The present invention relates to a semiconductor manufacturing process, and particularly to a method of manufacturing a MOS transistor.

2. Description of the Prior Art

The performance of MOS transistors has increased year after year with the diminution of critical dimensions and the advance of large-scale integrated circuits (LSI). The process of semiconductor has evolved to 65 nm (0.065 μm) in 2005 and is approaching 45 nm. In order to meet the demand of miniaturization of the semiconductor industry, the current channel length under the gate must meet the standard of 45 nm. To meet the 45 nm channel length requirement, it is crucial to control the critical dimension (CD) during the process of exposure of the gate so as to control the line width of the conductive layer (polysilicon layer for example) after the etching process. Because the current lithographic tool techniques are incapable of obtaining the ideal CD, trimming methods are employed to reduce the size of gate line width.

On the other hand, the improvement of carrier mobility so as to increase the speed performance of MOS transistors has become a major topic for study in the semiconductor field. For the known arts, attempts have been made to use a strained silicon layer, which has been grown epitaxially on a silicon substrate with a silicon germanium (SiGe) layer disposed therebetween. In this type of MOS transistor, a biaxial tensile strain occurs in the epitaxy silicon layer due to the silicon germanium which has a larger lattice constant than silicon, and, as a result, the band structure alters, and the carrier mobility increases. This enhances the speed performance of the MOS transistors.

For the known arts, an oxide hard mask layer is usually used for making a gate during a SiGe process. However, as shown in FIG. 1, an electron micrograph, when a diluted hydrofluoric acid (diluted HF) etching solution is used to remove the oxide hard mask layer on the gates, an oxide loss on shallow trench isolations (STI) often occurs. As shown in FIG. 1, the STI between two gates is eroded to form voids as the oxide hard mask layer is etched for removal. The voids extend to partially beneath the spacer, such that seams would form in the interlayer dielectric (ILD) layer obtained from the subsequent process. The seam further causes contact bridge, which is a serious problem.

To solve the problems mentioned above, a silicon-rich nitride material instead of oxide has been used as a hard mask layer; however, a poly bump issue occurs in the SiGe process. As shown in FIG. 2, a silicon-rich nitride hard mask layer 20 is used to form a gate structure (including a gate 22 and a gate dielectric layer 24). After a temporary spacer 26 is formed on the sidewall of the gate, the substrate 28 is etched to form recesses 30, and thereafter, a wet cleaning process is performed on the substrate 28 for cleaning the recesses 30. However, the hard mask layer is often formed in a poor shape with a round corner, such that the subsequently obtained temporary spacer 26 is too thin to protect the gate 22 nearby the round corner, and accordingly a polysilicon corner 32 of the gate 22 is easily exposed after the etching and the cleaning. The exposed polysilicon usually causes a poly bump problem during the epitaxial growth process.

Therefore, there is still a need for a novel SiGe process to solve the issues of oxide loss or poly bump as described above.

### SUMMARY OF THE INVENTION

The objective of the present invention is to provide a method of manufacturing a MOS transistor to avoid STI oxide loss or poly bump problems typically encountered in conventional SiGe processes.

The method of manufacturing a MOS transistor according to the present invention comprises steps as follows. A substrate is provided. A gate dielectric layer is formed on the substrate and a conductive layer is formed on the gate dielectric layer, a hard mask layer is formed on the conductive layer, and a photo resist layer is formed on the hard mask layer, sequentially. The photo resist layer comprises a tri-layer structure of a top photo resist layer, a silicon-containing photo resist layer, and a bottom anti-reflective coating (BARC). The etching selectivity ratio of the hard mask layer to silicon oxide is more than 2:1. Each layer of the photo resist layer is sequentially patterned until the BARC is patterned. The hard mask layer is patterned by using the BARC as a mask. A first etching process is performed on the conductive layer by using the patterned hard mask layer as a mask to form a gate. A first spacer is formed on sidewalls of the gate. A cap layer is conformally formed to cover the substrate. The cap layer is defined through a patterned photo resist layer, such that the cap layer has an opening at each of two sides of the gate. A second etching process is performed using the cap layer as a mask to form a recess on the substrate corresponding to each opening, wherein the patterned hard mask layer and the spacer-shaped cap layer protect the gate therebeneath from being bared due to the second etching process. An epitaxial growth process is performed for forming an epitaxial layer in each of the recesses. After forming the epitaxial layer, the patterned hard mask layer and the spacer-shaped cap layer are removed. A second spacer is formed on the first spacer.

In another aspect of the present invention, a method of manufacturing a MOS transistor is provided. The method comprises steps as follows. A substrate is provided. A gate dielectric layer is formed on the substrate, a conductive layer is formed on the gate dielectric layer, and a hard mask layer is formed on the conductive layer, sequentially. The etching selectivity ratio of the hard mask layer to silicon oxide is more than 2:1. A photo resist layer is formed on the hard mask layer. The photo resist layer comprises a tri-layer structure a top photo resist layer, a silicon-containing photo resist layer, and a bottom anti-reflective coating (BARC). Each layer of the photo resist layer is sequentially patterned until the BARC of the photo resist layer is patterned. The hard mask layer is patterned using the BARC of the photo resist layer as a mask. A first etching process is performed on the conductive layer by using the patterned hard mask layer as a mask to form a gate. A first spacer is formed on sidewalls of the gate. A cap layer is conformally formed to cover the substrate. An anisotropic etching process is performed on the cap layer, thereby to partially remove the cap layer and form a spacer-shaped cap layer on the first spacer and expose the substrate beside the spacer-shaped cap layer. A second etching process is performed using the spacer-shaped cap layer and the patterned hard mask layer as a mask to form a recess on the substrate exposed at each of two sides of he gate, wherein the patterned hard mask layer and the spacer-shaped cap layer protect the gate therebeneath from being bared due to the second etching process. An epitaxial growth process is performed for forming an epitaxial layer in each of the recesses. After forming the epitaxial layer, the patterned hard mask layer and the spacer-shaped cap layer are removed. A second spacer is formed on the first spacer.

In another aspect of the present invention, a method of manufacturing a MOS transistor is provided. The method comprises steps as follows. A substrate is provided. The substrate comprises a first active region for fabricating a first transistor and a second active region for fabricating a second transistor. A gate dielectric layer is formed on the substrate, a conductive layer is formed on the gate dielectric layer, and a hard mask layer is formed on the conductive layer, sequentially. The etching selectivity ratio of the hard mask layer to silicon oxide is more than 2:1. A first photo resist layer is formed on the hard mask layer, wherein the first photo resist layer comprises a tri-layer structure of a top photo resist layer, a silicon-containing photo resist layer, and a bottom anti-reflective coating (BARC). Each layer of the first photo resist layer is patterned until the BARC of the photo resist layer is patterned. The hard mask layer is patterned using the BARC of the first photo resist layer as a mask. A first etching process is performed on the conductive layer by using the patterned hard mask layer as a mask to form a first gate on the first active region and a second gate on the second active region. A first spacer and a second spacer are formed on sidewalls of the first gate and the second gate. A cap layer is conformally formed to cover the first active region and the second active region. The cap layer covering the second active region is partially removed to form a spacer-shaped cap layer on the second spacer and expose the substrate beside the spacer-shaped cap layer. A second etching process is performed using the spacer-shaped cap layer and the patterned hard mask layer as a mask to form a recess on the substrate exposed at each of two sides of the second gate, wherein the patterned hard mask layer and the spacer-shaped cap layer protect the second gate therebeneath from being bared due to the second etching process. An epitaxial growth process is performed for forming an epitaxial layer in each of the recesses. A second photo resist layer is formed to cover the second active region. The cap layer covering the first active region is partially removed to form a third spacer on the first spacer. The second photo resist layer is removed. A dielectric layer is formed to cover the first active region and the second active region. A third etching process is performed to partially remove the dielectric layer for forming a fourth spacer and a fifth spacer respectively on the third spacer and the spacer-shaped cap layer, and the patterned hard mask layer is exposed. The patterned hard mask layer is removed.

In another aspect of the present invention, a method of manufacturing a MOS transistor is provided. The method comprises steps as follows. A substrate is provided. The substrate comprises a first active region for fabricating a first transistor and a second active region for fabricating a second transistor. A gate dielectric layer is formed on the substrate, a conductive layer is formed on the gate dielectric layer, and a hard mask layer is formed on the conductive layer, sequentially. The etching selectivity ratio of the hard mask layer to silicon oxide is more than 2:1. A first photo resist layer is formed on the hard mask layer, wherein the first photo resist layer comprises a tri-layer structure of a top photo resist layer, a silicon-containing photo resist layer, and a bottom anti-reflective coating (BARC). Each layer of the first photo resist layer is patterned until the BARC of the photo resist layer is patterned. The hard mask layer is patterned using the BARC of the first photo resist layer as a mask. A first etching process is performed on the conductive layer by using the patterned hard mask layer as a mask to form a first gate on the first active region and a second gate on the second active region. A first spacer and a second spacer are formed on sidewalls of the first gate and the second gate. A cap layer is conformally formed to cover the first active region and the second active region. The cap layer covering the second active region is partially removed to form a spacer-shaped cap layer on the second spacer and expose the substrate beside the spacer-shaped cap layer. A second etching process is performed using the spacer-shaped cap layer and the patterned hard mask layer as a mask to form a recess on the substrate exposed at each of two sides of the second gate, wherein the patterned hard mask layer and the spacer-shaped cap layer protect the second gate therebeneath from being bared due to the second etching process. An epitaxial growth process is performed for forming an epitaxial layer in each of the recesses. A dielectric layer is formed to cover the first active region and the second active region. A third etching process is performed to partially remove the dielectric layer for simultaneously forming a third spacer and a fourth spacer on the first spacer and forming the fifth spacer on the spacer-shaped cap layer, and the patterned hard mask layer is exposed. The patterned hard mask layer is removed.

In the method of the present invention, a tri-layer photo resist layer is used to form a patterned hard mask layer having a sound shape and a small size, and the hard mask layer is used to form a gate. After the gate is formed, the hard mask layer is not removed until the epitaxial layers are formed. As such, the spacer-shaped cap layer formed on the sidewall of the gate also has a good configure due to the good-shaped hard mask layer. Both provide a good protection to the gate during the etching and the cleaning for the recesses such that the gate is not exposed and the poly bump issue is avoided. Additionally, since the etching selectivity ratio of the hard mask layer to silicon oxide is more than 2:1, STI oxide loss is insignificant when the hard mask layer is removed, and accordingly an STI oxide loss issue leading to contact bridge can be avoided.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is an electron micrograph of a conventional semiconductor transistor showing that STI oxide loss issue occurs in the conventional technology;

FIG. 2 is a schematically cross-sectional diagram showing that a corner of the hard mask is rounded in a conventional technology;

FIGS. 3 through 14 are schematically cross-sectional diagrams showing some embodiments of the method of manufacturing a MOS transistor according to the present invention;

FIGS. 15 through 20 are schematically cross-sectional diagrams showing another embodiment of the method of manufacturing a MOS transistor according to the present invention; and

FIGS. 21 through 23 are schematically cross-sectional diagrams showing further another embodiment of the method of manufacturing a MOS transistor according to the present invention.

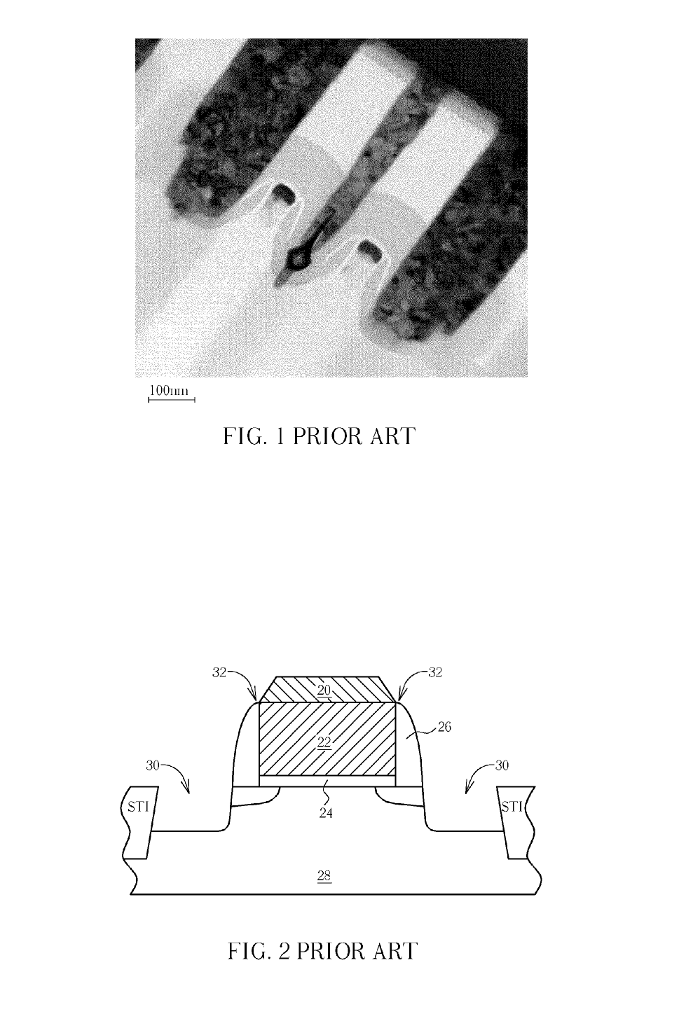

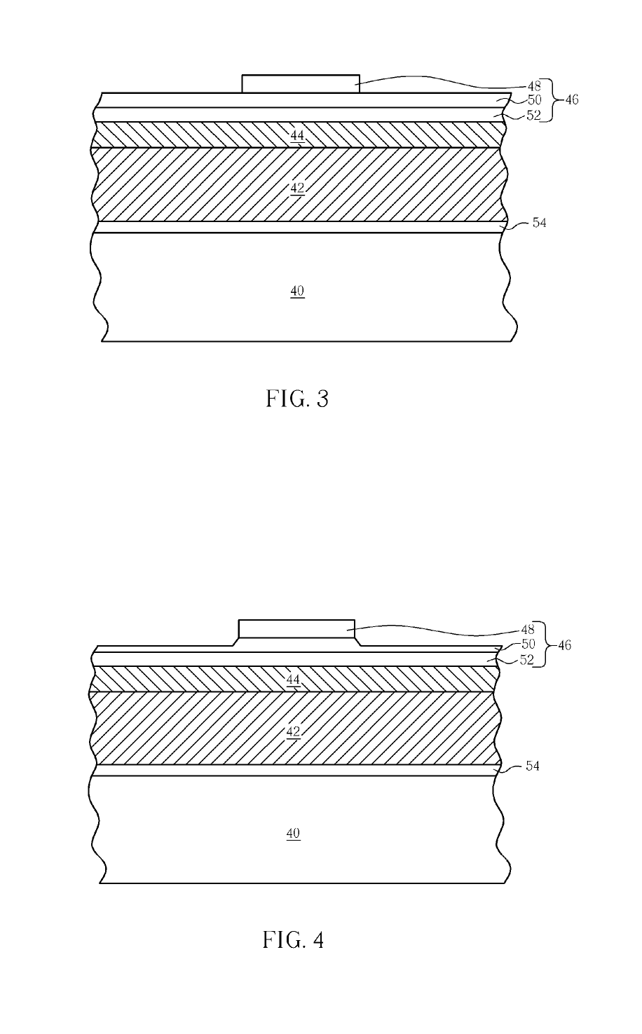

### DETAILED DESCRIPTION

In the method of forming an epitaxial layer in a MOS transistor manufacturing process according to the present invention, a tri-layer photo resist layer is utilized to pattern a hard mask layer having a sound shape substantially without a round corner and a small line width. Such hard mask layer is utilized to make a gate, and after the gate is formed, the hard mask layer is not subsequently removed as that usually done in conventional technologies, but the hard mask layer is removed after recesses are formed and epitaxial layers are formed in the recesses in an epitaxial process. The method of the present invention is easily integrated with current processes and has a low cost, and accordingly can be well applied to MOS transistor manufacturing processes. Some embodiments of the present invention are described hereinafter.

FIGS. 3 through 14 indicate an embodiment of the method of forming an epitaxial layer in a MOS transistor manufacturing process according to the present invention. First, as shown in FIG. 3, a substrate 40 is provided. The substrate may be a semiconductor substrate. Next, a conductive layer 42 is formed on the substrate 40, a hard mask layer 44 is formed on the conductive layer 42, and a photo resist layer 46 is formed on the hard mask layer 44, sequentially. The photo resist layer 46 comprises a tri-layer structure of a top photo resist layer 48, a silicon-containing photo resist layer 50, and a BARC 52. A dielectric layer 54 may be further formed between the conductive layer 42 and the substrate 40.

The conductive layer 42 may be formed by deposition, such as chemical vapor deposition (CVD) or plasma enhanced chemical vapor deposition (PECVD). The conductive layer 42 may comprise polysilicon or other conductive material. The hard mask layer 44 may comprise a material having an etching selectivity over silicon oxide of more than 2:1, with respect to a phosphoric acid etching solution. There is not an upper limit for the etching selectivity ratio. In view of common materials easily available, the etching selectivity ratio may be preferably between 2:1 and 5:1. Suitable materials may be, for example, silicon nitride, silicon-rich nitride, SiON, APF film (trade name, available from Applied Materials, Inc. of Santa Clara, Calif.), or SiC, but not limited thereto. The top photo resist layer 48 may be a 193 nm photo resist layer, which may be relatively thin, and accordingly, the resolution may be improved. The silicon-containing photo resist layer 50, serving as a medial layer, may contain 10-30% of silicon and has a function of anti-erosion. The BARC 52 may be a 365 nm (I-line) photo resist layer, which may improve adhesion and provide a function of anti-reflection. Such tri-layer photo resist layers and the patterning processes are taught in co-pending and co-assigned U.S. patent application Ser. No. 11/620,028, the contents of which are incorporated herein by reference.

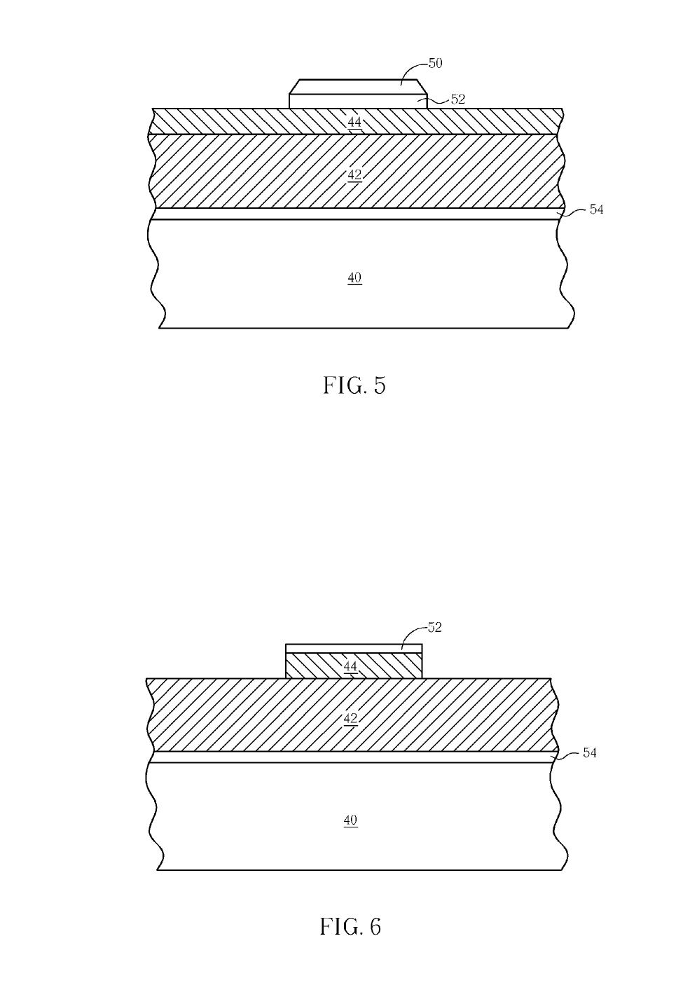

After the tri-layer photo resist layer 46 is formed on the hard mask layer 44, a photolithographic process is performed to pattern the top photo resist layer 48, as shown in FIG. 3. Thereafter, as shown in FIG. 4, an etching process, such as dry etching, is performed using the patterned top photo resist layer 48 as an etching mask to pattern the silicon-containing photo resist layer 50, while it is not completely etched through. Thereafter, the remaining top photo resist layer 48 is removed. Thereafter, please refer to FIG. 5, the silicon-containing photo resist layer 50 per se is etched using the patterned silicon-containing photo resist layer 50 as a mask until the BARC 52 is exposed. Thereafter, the BARC 52 is etched using the etched-through silicon-containing photo resist layer 50 as a mask until the hard mask layer 44 is exposed to pattern the BARC 52. In this etching procedure, the thickness of the whole silicon-containing photo resist layer 50 is reduced. Generally, the silicon-containing photo resist layer 50 would be completely depleted without any remainder. In case the silicon-containing photo resist layer 50 is not completely depleted, it can be removed by a further etching procedure or a washing procedure.

Thereafter, please refer to FIG. 6; an etching process is performed on the hard mask layer 44 using the patterned BARC 52 as an etching mask to pattern the hard mask layer 44. In addition, the thickness of the BARC 52 is also diminished in such etching process, since the patterned hard mask layer 44 is defined using the patterned BARC 52 as an etching mask. In another embodiment of the present invention, a trimming process, i.e. trim down etching process, may be performed on the stack of the patterned hard mask layer and the BARC to further attain the line edge shortage after the etching process. The trimming process may be a plasma etching process. For example, CF₄ and CHF₃ may be used as etching gases in a ratio of 50/45 (CF₄/CHF₃).

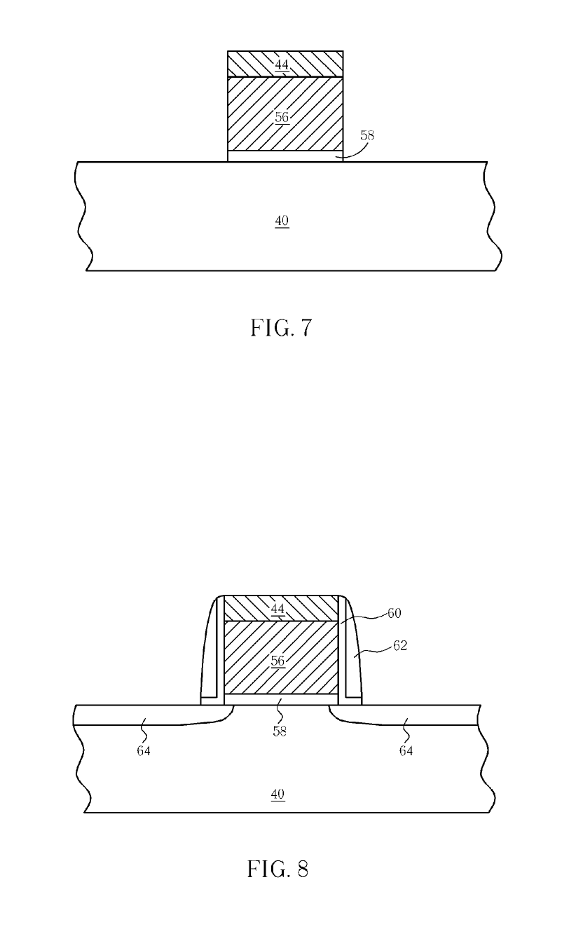

Please refer to FIG. 7. Because the hard mask layer 44 has a significant etching selectivity ratio to the conductive layer 42, the BARC 52 and the hard mask layer 44 are used as the templates for an etching transfer step to define the pattern of the gate 56 from the conductive layer 42. Thereafter, the dielectric layer 54 is etched to form a gate dielectric layer 58. Thereafter, the BARC 52 is removed.

Thereafter, please refer to FIG. 8. A spacer may be optionally formed on the sidewall of the gate 56. The spacer may include an L-shaped or linear offset spacer, D-shaped spacer, of a combination thereof and comprise a material such as oxide or nitride. As shown in FIG. 8, an offset spacer 60 is formed on the sidewall of the gate 56, and a D-shaped spacer 62 is formed on the offset spacer 60. Thereafter, an ion implantation process is optionally performed to form lightly doped drains (LDD) 64 in the substrate 40 at two sides of the gate 56.

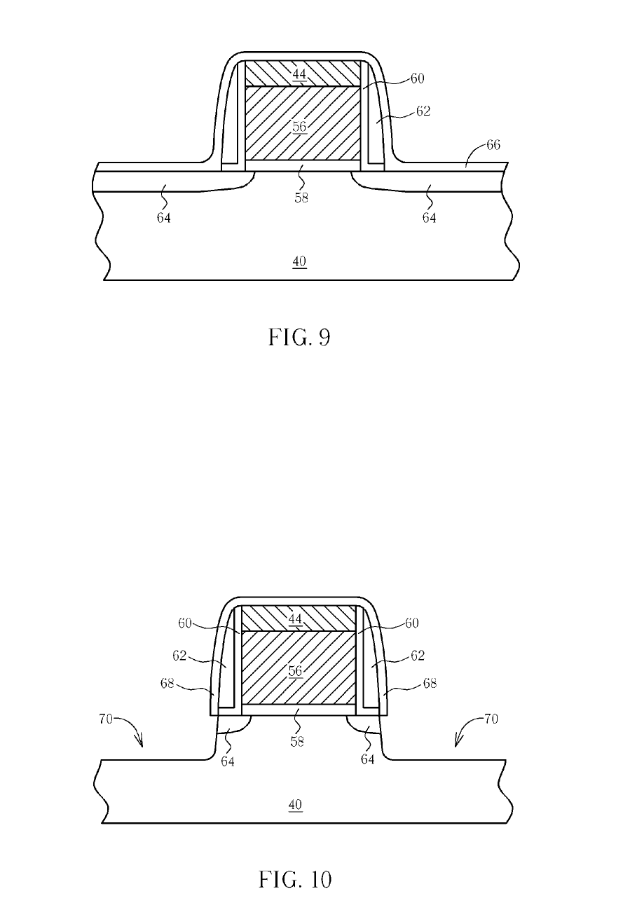

Thereafter, please refer to FIG. 9. A cap layer 66 is conformally deposited to cover the substrate 40 and the hard mask layer 44. Thereafter, an etching is performed to define the cap layer 66 to have openings for forming recesses in subsequent steps. If a photo resist layer is previously defined to have the recess pattern, and then the cap layer 66 is etched through the patterned photo resist layer. As a result, a patterned cap layer 68 will be formed as shown in FIG. 10 to have openings for exposing the substrate for forming recesses. Thereafter, the exposed substrate is partially removed using the cap layer 68 as a mask, forming recesses 70.

Alternatively, an anisotropic etching process may be performed directly on the cap layer 66, such that a spacer-shaped cap layer 69 as shown in FIG. 11 will be formed on the spacer 62 and the substrate beside the spacer-shaped cap layer 69 and the patterned hard mask layer 44 are exposed. Thereafter, the exposed substrate, i.e. the recess regions, is partially removed using the patterned hard mask layer 44 and the spacer-shaped cap layer 69 as a mask to form recesses 70.

The method for forming the recesses 70 may be dry etching and/or wet etching. The cap layer 66 may comprise silicon nitride for convenient removal by wet etching in the subsequent process. Thereafter, a wet cleaning process is optionally performed to remove impure residue on the surface of the recess 70.

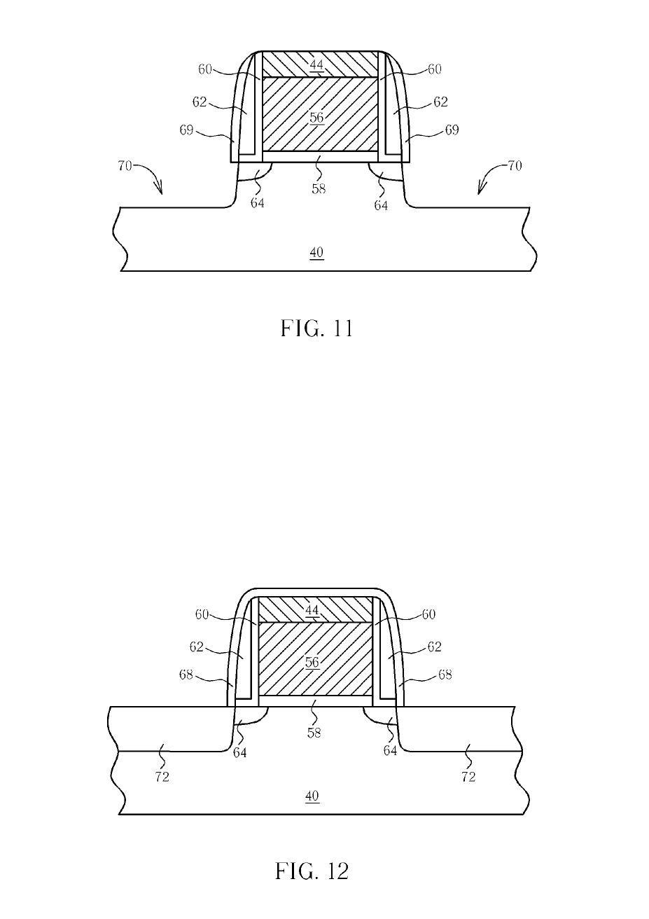

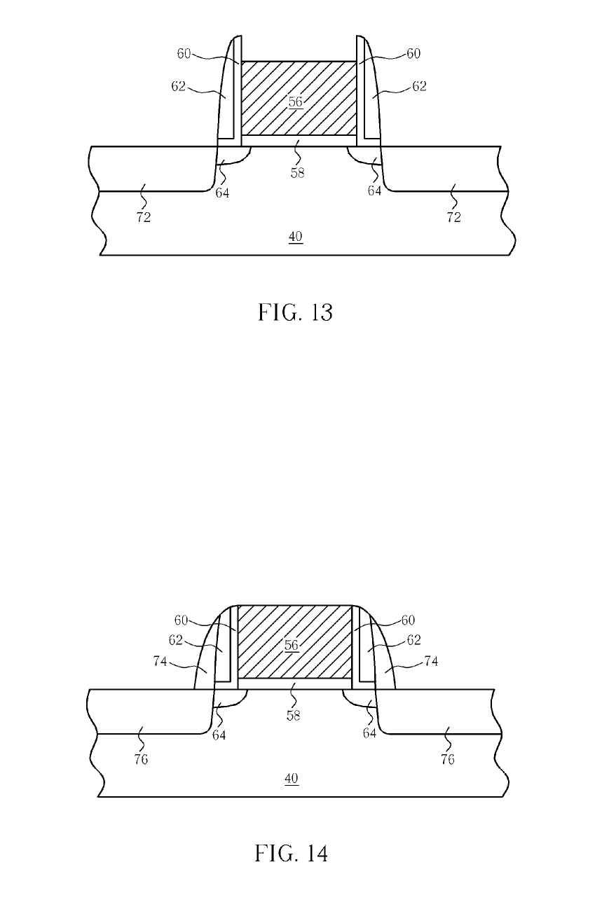

Thereafter, as shown in FIG. 12, an epitaxial growth process, such as selective epitaxial growth (SEG) process, is performed to form an epitaxial layer 72 in each of he recesses 70. For example, a SiGe epitaxial layer may be used for manufacturing a PMOS, and a SiC epitaxial layer may be used for manufacturing an NMOS, but not limited thereto. The epitaxial layer may rise to have a height greater than that of the top plane of the original substrate. After the epitaxial layer 72 is formed, a wet etching process is performed. A phosphoric acid etching solution may be used for a long time etching. The hard mask layer 44 comprises silicon nitride material of same properties as that of the cap layer 68 or 69. The silicon nitride has a different etching rate relative to silicon oxide. Therefore, both can be removed simultaneously in a same process of wet etching, as shown in FIG. 13. In the present invention, the hard mask layer 44 does not comprise silicon oxide, and accordingly it can be removed without using a diluted HF etching solution. Therefore, the STI oxide loss issue will not occur.

Thereafter, as shown in FIG. 14, a dielectric layer (not shown) is deposited on the substrate 40 and the gate 56. The dielectric layer may be formed by oxidation, chemical vapor deposition (CVD), or plasma enhanced chemical vapor deposition (PECVD). The material may be oxide, oxy-nitride, nitrogen-containing dielectric materials or a combination thereof, or a multi-layer structure thereof. Then, an etching back process is performed to form a spacer 74 on the sidewalls of the gate 56 and the gate dielectric layer 58. The spacer 74 may cover a portion of the epitaxial layer. Thereafter, a source/drain 76 is formed in each of the epitaxial layers in the substrate 40 by an ion implantation process using the gate 56 and the spacer 74 as a mask, or the source/drain is simultaneously formed with the epitaxial layer by in-situ doping when the epitaxial layer is forming, to obtain a MOS transistor.

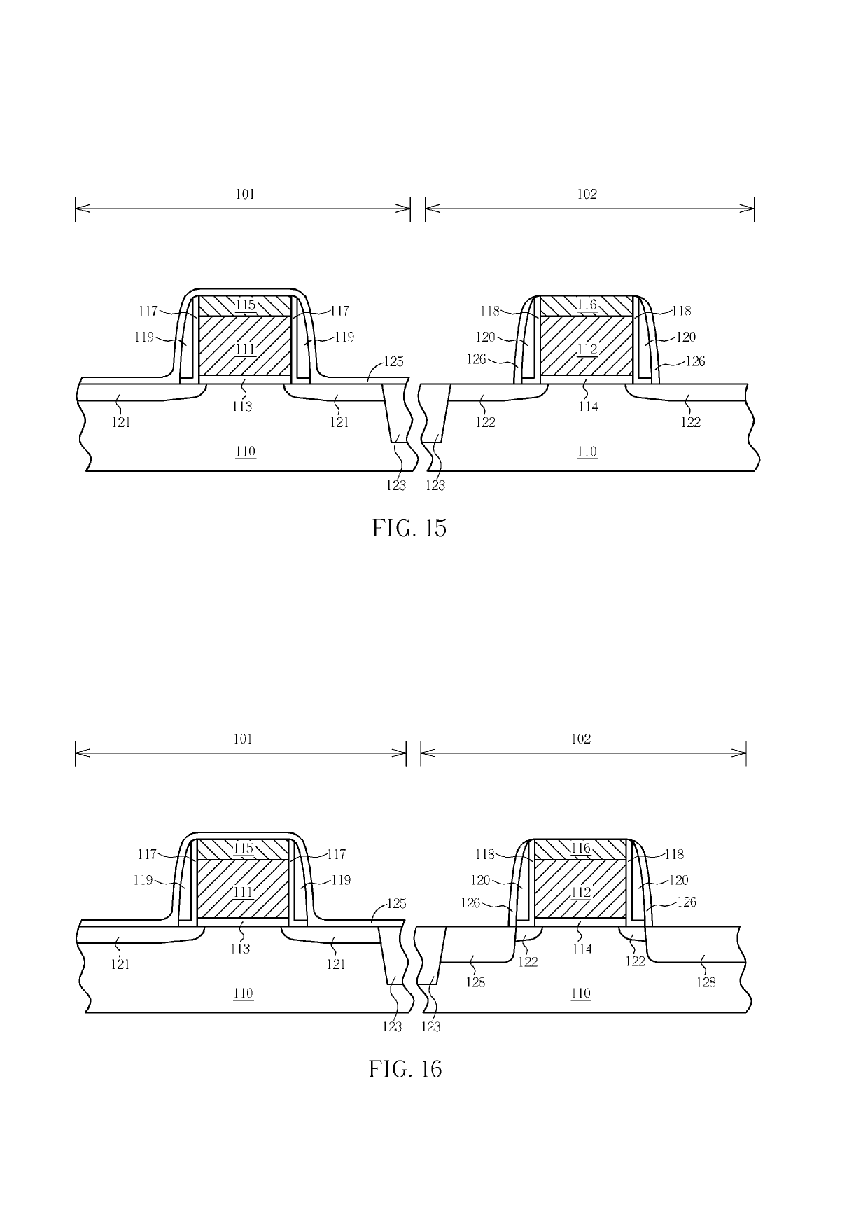

According to the method of the present invention described above, the present invention may be applied to the manufacturing process to simultaneously form a PMOS and a NMOS on a same substrate. Please refer to FIGS. 15 through 20, schematically cross-sectional diagrams showing another embodiment of the method of manufacturing a MOS transistor according to the present invention. FIG. 15 shows a substrate 110 comprising a first active region 101 for fabricating a first transistor and a second active region 102 for fabricating a second transistor. FIG. 15 also shows a first gate 111 and a second gate 112 defined on the substrate 110 using the tri-layer photo resist layer and the hard mask layer by the steps in the present invention as described above. The gate dielectric layers 113 and 114 are disposed between the first gate 111, the second gate 112 and the substrate 110 respectively. The patterned hard mask layers 115 and 116 remains on the top of the gate, yet. A spacer is formed on each of sidewalls of the first gate 111 and the second gate 112. The spacer may include the offset spacers 117, 118 and spacers 119, 120. LDD 121 and 122 are formed on the substrate 110 at two sides of the first gate 111 and the second gate 112. An STI 123 electrically separates each device. In FIG. 15, a cap layer 125 is formed to cover the first active region 101 and the second active region 102. The cap layer 125 comprises dielectric material, such as silicon nitride. A photo resist layer is formed to cover the first active region 101, and the cap layer 125 covering the second active region 102 is partially removed. The portion of the cap layer 125 on the sidewall of the second gate 112 is remained to form a spacer-shaped cap layer 126.

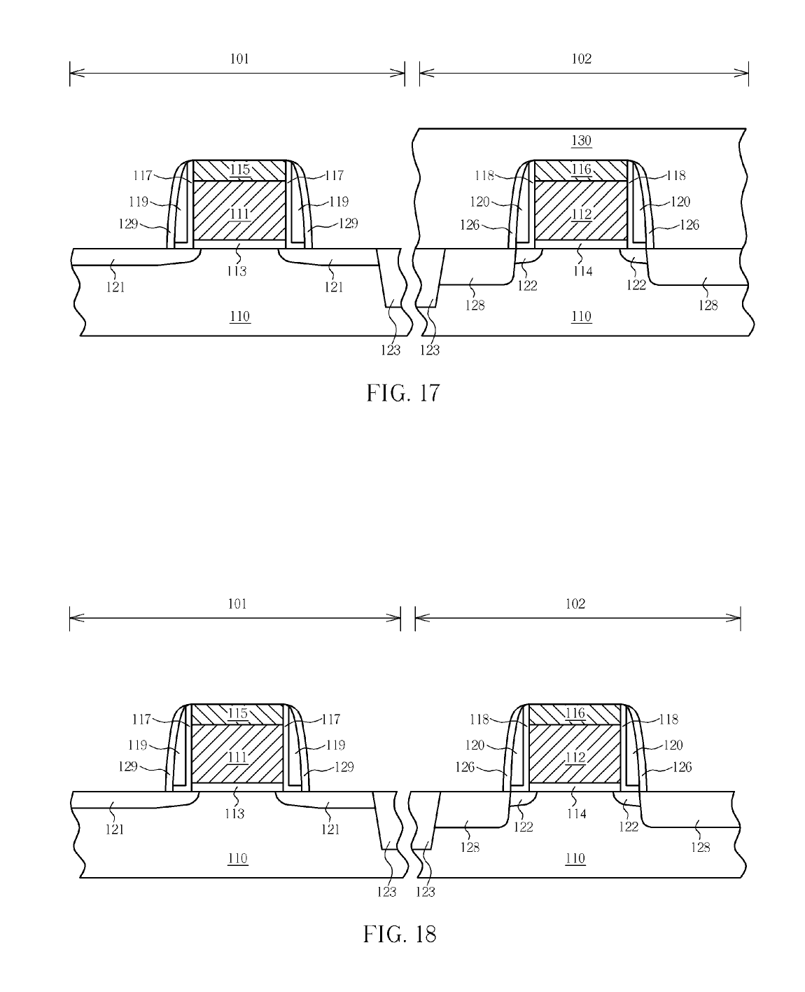

Please refer to FIG. 16. An etching process is performed to form a recess (not shown) on the substrate 110 at each of two sides of the spacer-shaped cap layer 126 on the second gate 112. The recesses may be cleaned as desired. An epitaxial growth process is performed to form an epitaxial layer 128 in each of the recesses. Thereafter, please refer to FIG. 17. A photo resist layer 130 is defined to cover the second active region 102. The cap layer 125 covering the first active region 101 is etched and partially removed, leaving the portion of the cap layer 125 on the sidewall of the first gate 111 to serve as a spacer 129. The width of the spacer 129 may be controlled to be substantially the same as that of the spacer-shaped cap layer 126. Such that, the first transistor and the second transistor thus formed may have spacers with desired total sizes.

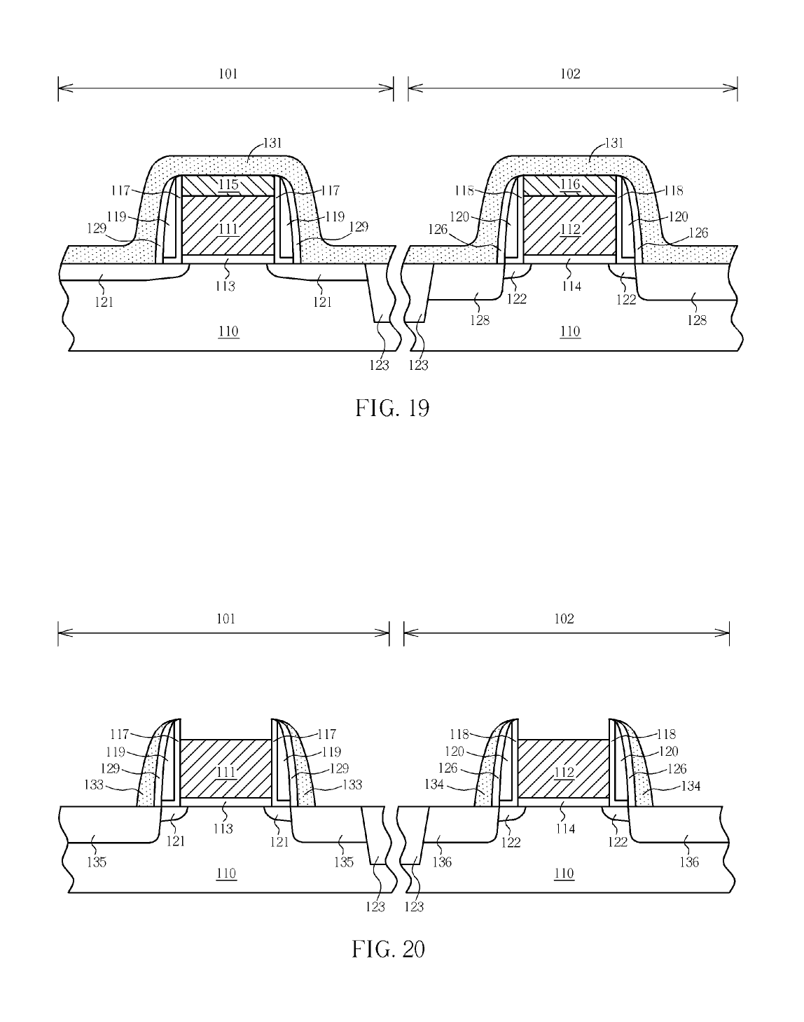

Please refer to FIG. 18. The photo resist layer 130 is removed. Please refer to FIG. 19. A dielectric layer 131 is formed on the first active region 101 and the second active region 102 to cover the first active region 101 and the second active region 102. Thereafter, referring to FIG. 20, an etching process is performed to partially remove the dielectric layer 131, so as to form spacers 133 and 134 respectively on the spacer 129 of the first gate 111 and the spacer-shaped cap layer 126 on the sidewall of the second gate 112 and to expose hard mask layers 115 and 116. Thereafter, the patterned hard mask layers 115 and 116 are removed. The removal of the patterned hard mask layers 115 and 116 may be performed by a wet etching, partial dry etching and partial wet etching, or dry etching, and it may depend on the etching selectivity ratio between the material and the material of the gates, substrate, spacers. Finally, an ion implantation process is performed using each gate and each spacer as masks to respectively form a source/drain 135 and 136 in the substrate 110 at each of two sides of the spacers 133 and 134 of the first gate 111 and the second gate 112, to form the first transistor and the second transistor. Alternatively, the source/drain 136 may be formed simultaneously with the epitaxial layer 128 by in-situ doping when the epitaxial layer is forming.

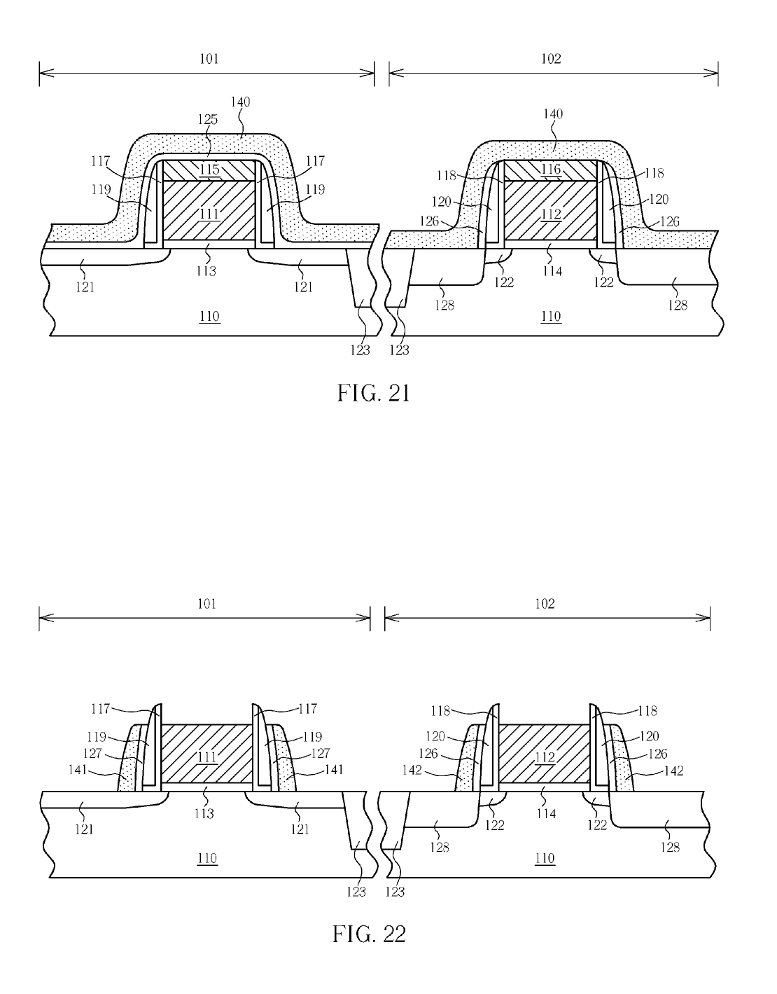

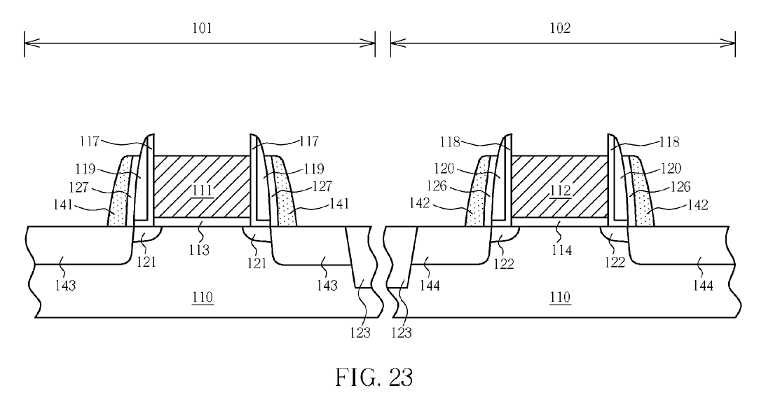

According to the method of the present invention described above, the present invention may be modified in various ways. FIGS. 21 through 23 show further another embodiment of the method of simultaneously forming a PMOS and a NMOS on a same substrate. FIG. 21 shows a status following that of FIG. 16 described in the above embodiment. Recesses (not shown) are formed on the substrate 110 at two side of the spacer-shaped cap layer 126 by an etching process. The recesses may be cleaned as desired. An epitaxial growth process is performed to form an epitaxial layer 128 in each of the recesses. Thereafter, a difference from the embodiment described above is that a dielectric layer 140 is directly formed to cover the first active region 101 and the second active region 102, instead of removing the cap layer 125 covering the first active region 101 as shown in FIG. 17. Thereafter, as shown in FIG. 22, an etching process is performed to partially remove the dielectric layer 140 and the cap layer 125, such that a spacer 127 and a spacer 141 are simultaneously formed from the cap layer 125 and the dielectric layer 140 on a sidewall of the first gate 111 and a spacer 142 is formed from the dielectric layer 140 on the spacer-shaped cap layer 126 of the second gate 112, and the patterned hard mask layers 115 and 116 are exposed. Thereafter, the patterned hard mask layers 115 and 116 are removed. The removal of the patterned hard mask layers 115 and 116 may be performed by a wet etching, partial dry etching and partial wet etching, or dry etching, and it may depend on the etching selectivity ratio between the material and the material of the gates, substrate, spacers. Finally, referring to FIG. 23, a source/drain 143 and 144 are formed in the substrate 110 at each of two sides of the spacers 141 and 142 of the first gate 111 and the second gate 112 using each gate and each spacer as masks, to form the first transistor and the second transistor. Likewise, the source/drain 144 also may be formed simultaneously with the epitaxial layer 128 by in-situ doping when the epitaxial layer is forming.

In this embodiment, the cap layer 125 covering the first active region 101 and the spacer-shaped cap layer 126 on the sidewall of the second gate 112 are not removed, but directly covered with a dielectric layer 140, and then they are anisotropically dry etched together to form spacers. Accordingly there are other advantages in addition to the advantage of avoiding STI oxide loss and gate bump. In conventional techniques, since the cap layer and the spacer-shaped cap layer are removed by wet etching immediately after the epitaxial layers are formed, a specific material suitable for wet etching, such as Singen SiN, is needed, and the wet etching is slow. In the embodiment of the present invention, the choice for the material of the cap layer 125 is wider, for example, BTBAS SiN (BTBAS stands for bis-(t-butylamino)silane) may be utilized, without being limited to the wet etching selectivity ratio as the conventional techniques, and thus the process is faster and without the disadvantages of using Singen SiN.

All combinations and sub-combinations of the above-described features also belong to the present invention. Those skilled in the art will readily observe that numerous modifications and alterations of the device and method may be made while retaining the teachings of the invention.

What is claimed is:

1. A method of manufacturing a MOS transistor, comprising:
providing a substrate;
sequentially forming a gate dielectric layer on the substrate, a conductive layer on the gate dielectric layer, a hard mask layer on the conductive layer, and a photo resist layer on the hard mask layer, wherein, the photo resist layer comprises a tri-layer structure of a top photo resist layer, a silicon-containing photo resist layer, and a bottom anti-reflective coating (BARC), and the etching selectivity ratio of the hard mask layer to silicon oxide is more than 2:1;
sequentially patterning each layer of the photo resist layer until the BARC is patterned;
patterning the hard mask layer by using the bottom anti-reflective coating as a mask;
performing a first etching process on the conductive layer by using the patterned hard mask layer as a mask to form a gate;
forming a first spacer on a sidewall of the gate;
conformally forming a cap layer on the substrate;
defining the cap layer through a patterned photo resist layer thereby to allow the cap layer has an opening on the substrate at each of two sides of the gate;
performing a second etching process using the cap layer as a mask to form a recess on the substrate corresponding to each opening, wherein the patterned hard mask layer and the cap layer protect the gate therebeneath from being bared due to the second etching process;
performing an epitaxial growth process for forming an epitaxial layer in each of the recesses; and
after forming the epitaxial layer, removing the patterned hard mask layer and the cap layer; and
forming a second spacer on the first spacer.

2. The method of claim 1, wherein the hard mask layer comprises silicon nitride, silicon-rich nitride, SiON, APF film, or SiC.

3. The method of claim 1, after forming the recesses, further comprising a step of performing a wet cleaning process on the substrate.

4. The method of claim 1, after patterning the hard mask layer using the BARC as a mask, further comprising performing a trimming process on the hard mask layer, thereby to reduce the line width of the patterned hard mask layer.

5. The method of claim 1, wherein the epitaxial layer comprises epitaxial SiGe.

6. A method of manufacturing a MOS transistor, comprising:
providing a substrate;
sequentially forming a gate dielectric layer on the substrate, a conductive layer on the gate dielectric layer, and a hard mask layer on the conductive layer, wherein, the etching selectivity ratio of the hard mask layer to silicon oxide is more than 2:1;
forming a photo resist layer on the hard mask layer, wherein the photo resist layer comprises a tri-layer structure of a top photo resist layer, a silicon-containing photo resist layer, and a bottom anti-reflective coating (BARC);
sequentially patterning each layer of the photo resist layer until the BARC of the photo resist layer is patterned;
patterning the hard mask layer by using the BARC of the photo resist layer as a mask;
performing a first etching process on the conductive layer by using the patterned hard mask layer as a mask to form a gate;
forming a first spacer on a sidewall of the gate;
conformally forming a cap layer on the substrate;
performing an anisotropic etching process directly on the cap layer thereby to partially remove the cap layer, form a spacer-shaped cap layer on the first spacer, and expose the substrate beside the spacer-shaped cap layer;
performing a second etching process using the spacer-shaped cap layer and the patterned hard mask layer as a mask to form a recess on the substrate exposed at each of two sides of he gate, wherein the patterned hard mask layer and the spacer-shaped cap layer protect the gate therebeneath from being bared due to the second etching process;
performing an epitaxial growth process for forming an epitaxial layer in each of the recesses;
after forming the epitaxial layers, removing the patterned hard mask layer and the spacer-shaped cap layer; and
forming a second spacer on the first spacer.

7. The method of claim 6, wherein the epitaxial layers comprise epitaxial SiGe.

8. The method of claim 6, wherein the hard mask layer comprises silicon nitride, silicon-rich nitride, SiON, APF film, or SiC.

9. The method of claim 6, wherein removing the patterned hard mask layer and the spacer-shaped cap layer is performed using a phosphoric acid etching solution.

10. The method of claim 6, after forming the recesses, further comprising performing a wet cleaning process on the substrate.

11. The method of claim 6, after patterning the hard mask layer by using the BARC of the photo resist layer as a mask, further comprising performing a trimming process on the hard mask layer, thereby to reduce the line width of the patterned hard mask layer.

12. A method of manufacturing a MOS transistor, comprising:
providing a substrate comprising a first active region for fabricating a first transistor and a second active region for fabricating a second transistor;
sequentially forming a gate dielectric layer on the substrate, a conductive layer on the gate dielectric layer, and a hard mask layer on the conductive layer, wherein, the etching selectivity ratio of the hard mask layer to silicon oxide is more than 2:1;
forming a first photo resist layer on the hard mask layer, wherein the first photo resist layer comprises a tri-layer structure of a top photo resist layer, a silicon-containing photo resist layer, and a bottom anti-reflective coating (BARC);
sequentially patterning each layer of the first photo resist layer until the BARC of the photo resist layer is patterned;
patterning the hard mask layer by using the BARC of the first photo resist layer as a mask;
performing a first etching process on the conductive layer by using the patterned hard mask layer as a mask to form a first gate on the first active region and a second gate on the second active region;
forming a first spacer and a second spacer on sidewalls of the first gate and the second gate;
conformally forming a cap layer covering the first active region and the second active region;
partially removing the cap layer covering the second active region to form a spacer-shaped cap layer on second spacer and expose the substrate beside the spacer-shaped cap layer;
performing a second etching process using the spacer-shaped cap layer and the patterned hard mask layer to form a recess on the substrate exposed at each of two sides of the second gate, wherein the patterned hard mask layer and the spacer-shaped cap layer protect the second gate therebeneath from being bared due to the second etching process;
performing an epitaxial growth process for forming an epitaxial layer in each of the recesses;
forming a second photo resist layer covering the second active region;
partially removing the cap layer covering the first active region to form a second spacer on the first spacer;
removing the second photo resist layer;
forming a dielectric layer covering the first active region and the second active region;
performing a third etching process to partially remove the dielectric layer for forming a fourth spacer and a fifth spacer respectively on the third spacer and the spacer-shaped cap layer and exposing the patterned hard mask layer; and
removing the patterned hard mask layer.

13. The method of claim 12, wherein removing the patterned hard mask layer is performed by the third etching process.

14. The method of claim 12, wherein removing the patterned hard mask layer is performed by a wet etching process.

15. The method of claim 12, wherein the hard mask layer comprises silicon nitride, silicon-rich nitride, SiON, APF film, or SiC.

16. The method of claim 12, after forming the recesses, further comprising a step of performing a wet cleaning process on the substrate.

17. A method of manufacturing a MOS transistor, comprising:
providing a substrate comprising a first active region for fabricating a first transistor and a second active region for fabricating a second transistor;
sequentially forming a gate dielectric layer on the substrate, a conductive layer on the gate dielectric layer, and a hard mask layer on the conductive layer, wherein, the etching selectivity ratio of the hard mask layer to silicon oxide is more than 2:1;
forming a first photo resist layer on the hard mask layer, wherein the first photo resist layer comprises a tri-layer structure of a top photo resist layer, a silicon-containing photo resist layer, and a bottom anti-reflective coating (BARC);
sequentially patterning each layer of the first photo resist layer until the BARC of the photo resist layer is patterned;
patterning the hard mask layer by using the BARC of the first photo resist layer as a mask;
performing a first etching process on the conductive layer by using the patterned hard mask layer as a mask to form a first gate on the first active region and a second gate on the second active region;
forming a first spacer and a second spacer on sidewalls of the first gate and the second gate;
conformally forming a cap layer covering the first active region and the second active region;
partially removing the cap layer covering the second active region to form a spacer-shaped cap layer on the second spacer and expose the substrate beside the spacer-shaped cap layer;
performing a second etching process using the spacer-shaped cap layer and the patterned hard mask layer as a mask to form a recess on the substrate exposed at each of two sides of the second gate, wherein the patterned hard mask layer and the spacer-shaped cap layer protect the second gate therebeneath from being bared due to the second etching process;
performing an epitaxial growth process for forming an epitaxial layer in each of the recesses;
forming a dielectric layer covering the first active region and the second active region;
performing a third etching process to partially remove the dielectric layer for simultaneously forming a third spacer and a fourth spacer on the first spacer and forming a fifth spacer on the spacer-shaped cap layer, and exposing the patterned hard mask layer; and
removing the patterned hard mask layer.

18. The method of claim 17, wherein removing the patterned hard mask layer is performed by the third etching process.

19. The method of claim 17, wherein removing the patterned hard mask layer is performed by a wet etching process.

20. The method of claim 17, wherein the hard mask layer comprises silicon nitride, silicon-rich nitride, SiON, APF film, or SiC.

21. The method of claim 17, after forming the recesses, further comprising a step of performing a wet cleaning process on the substrate.
